(19) United States
(12) Patent Application Publication
(10) Pub. No.: US 2026/0165170 A1
(43) Pub. Date: Jun. 11, 2026

(54) CHIP EMBEDDED PACKAGE

(71) Applicant: SHENNAN CIRCUITS CO.,LTD., SHENZHEN (CN)

(72) Inventors: KAI ZHU, SHENZHEN (CN); ZEDONG WANG, SHENZHEN (CN); JUN WU, SHENZHEN (CN)

(21) Appl. No.: 19/415,814

(22) Filed: Dec. 11, 2025

Related U.S. Application Data
(63) Continuation of application No. PCT/CN2025/092414, filed on Apr. 30, 2025.

(30) Foreign Application Priority Data
Dec. 9, 2024 (CN) 202411805637.8

(51) Int. Cl. H10W 70/68; H10W 40/20; H10W 40/22; H10W 70/652; H10W 74/10

(52) U.S. Cl. CPC H10W 70/682; H10W 40/228; H10W 40/235; H10W 70/652; H10W 74/114

(57) ABSTRACT

The present application provides a chip embedded package. The chip embedded package includes a base circuit board, a chip unit, an encapsulation layer, and a plurality of connecting members. The chip unit includes a metal substrate and a chip. A step defining a first surface and a second surface is formed on the metal substrate, and the chip is fixedly connected to the second surface. The first surface protrudes from the second surface, and the second surface extends to at least one side edge of the metal substrate. The connecting members include a first connecting member. An end of the first connecting member is connected to a first side of the chip, and another end of the first connecting member crosses the second surface to horizontally extend to a first side of the base circuit board, and extends to a board edge to be exposed.

### CROSS REFERENCE TO RELATED APPLICATIONS

The present disclosure is a continuation of International Patent Application No. PCT/CN2025/092414, filed on Apr. 30, 2025, which claims priority to Chinese Patent Application No. 202411805637.8, filed on Dec. 9, 2024, the entire contents of these applications are incorporated herein by reference.

### TECHNICAL FIELD

The present disclosure relates to the field of chip packaging technologies, and in particular to a chip embedded package.

### BACKGROUND

With a continuous advancement of global energy structure transformation, electrical energy has become an increasingly important form of energy. A power chip has a characteristic of high conversion efficiency, but a current packaging method of the power chip has an excessive parasitic parameter, which affects the switching frequency of the power chip.

Embedding the power chip into a printed circuit board has become one of the optimal solutions to reduce an integration parameter.

However, after the power chip is embedded into the printed circuit board, problems such as electrical breakdown or electrical leakage are prone to occur.

### SUMMARY

Some embodiments of the present disclosure may provide a chip embedded package including a base circuit board, at least one chip unit, an encapsulation layer, and a plurality of connecting members. At least one mounting groove may be defined on a first side of the base circuit board. Each of the at least one chip unit may be fixedly mounted in a corresponding one of the at least one mounting groove, and each of the at least one chip unit may include at least one metal substrate and at least one chip. A step defining a first surface and a second surface may be formed on a first side of each of the at least one metal substrate, and a corresponding one of the at least one chip may be fixedly connected to the second surface. The first surface may protrude from the second surface, and the second surface may extend to at least one side edge of a corresponding one of the at least one metal substrate. The encapsulation layer may be attached to the first side of the base circuit board and fill gaps between the base circuit board and the at least one chip unit. An end of each of the plurality of connecting members may be connected to a corresponding electrode of a corresponding one of the at least one chip, and another end of each of the plurality of connecting members may extend to a first side of the encapsulation layer to be exposed. The plurality of connecting members may include a first connecting member, an end of the first connecting member may be connected to a first side of a corresponding one of the at least one chip, and another end of the first connecting member may cross the second surface in the encapsulation layer to horizontally extend to the first side of the base circuit board, and may extend to a board edge along the first side of the base circuit board to be exposed. A projection of the first connecting member projected on a corresponding one of the at least one metal substrate may be entirely located on the second surface.

### BRIEF DESCRIPTION OF THE DRAWINGS

FIG. 1 is a schematic structural view of a chip embedded package according to a first embodiment of the present disclosure.

FIG. 2 is a schematic structural view of a chip embedded package according to a second embodiment of the present disclosure.

FIG. 3 is an enlarged schematic view of a first connecting member shown in FIG. 2.

FIG. 4 is an enlarged schematic view of a second connecting member shown in FIG. 2.

FIG. 5 is a partial structural schematic view of a metal substrate and a heat dissipation device according to some embodiments of the present disclosure.

FIG. 6 is a top schematic view of a first side of a metal substrate according to some embodiments of the present disclosure.

FIG. 7 is a schematic structural view of a metal substrate according to another embodiment of the present disclosure.

FIG. 8 is a schematic structural view of a chip embedded package according to a third embodiment of the present disclosure.

FIG. 9 is a schematic structural view of a chip embedded package according to a fourth embodiment of the present disclosure.

### DETAILED DESCRIPTION

The technical solutions of the embodiments of the present disclosure may be described clearly and completely below in conjunction with the drawings of the embodiments of the present disclosure. It is apparent that the embodiments described are merely a part of the embodiments of the present disclosure, rather than all of the embodiments. Based on the embodiments of the present disclosure, all other embodiments obtained by those skilled in the art without inventive effort shall fall within the protection scope of the present disclosure.

It should be noted that if there are directional indications (e.g., up, down, left, right, front, back, etc.) in the embodiments of the present disclosure, the directional indications may be used only to explain the relative positional relationships or motion conditions of the components under a certain posture. When the posture changes, the corresponding directional indications may be changed accordingly.

In addition, if there are descriptions involving “first”, “second”, and the like in the embodiments of the present disclosure, the descriptions of “first”, “second”, and the like may be used merely for descriptive purposes and may not be construed as indicating or implying relative importance or implicitly specifying the number of the indicated technical features. Therefore, features defined by “first” and “second” may expressly or implicitly include at least one such feature. Furthermore, the technical solutions among the various embodiments may be combined with each other, but such combination has to be based on the capability of realization by those skilled in the art. When the combination of technical solutions is contradictory or cannot be realized, it shall be understood that such combination does not exist and is not within the protection scope of the present disclosure.

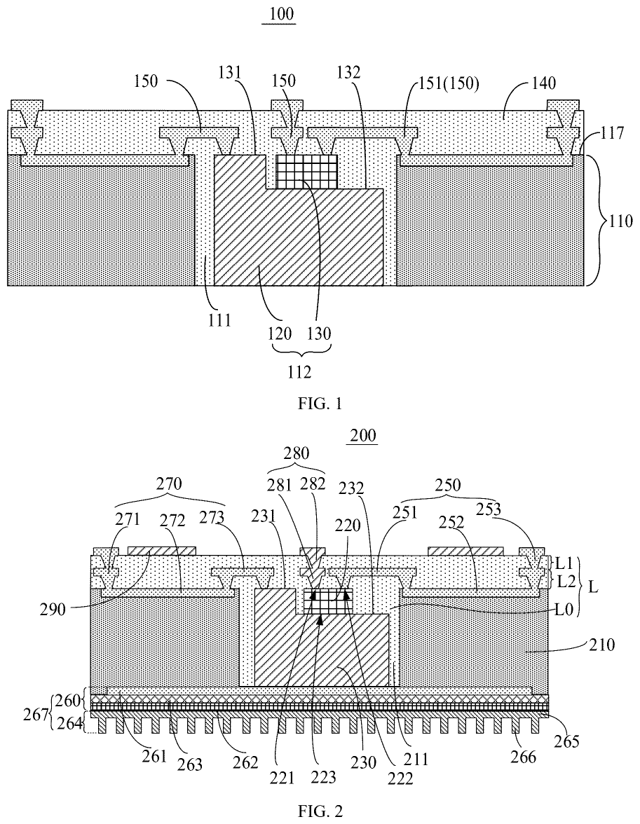

As shown in FIG. 1, FIG. 1 is a schematic structural view of a chip embedded package according to a first embodiment of the present disclosure.

The chip embedded package 100 of the embodiment may include a base circuit board 110, at least one chip unit 112, an encapsulation layer 140, and a plurality of connecting members 150.

The base circuit board 110 may be a printed circuit board (PCB) with a prepared circuit structure. The base circuit board 110 may function as a basic framework for chip embedding. A circuit of the base circuit board 110 may be patterned. The base circuit board 110 may be a multi-layer board with only through-hole interconnections, or a high density interconnector (HDI) board including blind-hole interconnections. A structure (not shown in the drawings) of the base circuit board 110 may be set according to actual needs.

The chip unit 112 may include at least one metal substrate 120 and at least one chip 130. Each of the at least one chip 130 may include a power chip, such as an insulated-gate bipolar transistor (IGBT) or a metal-oxide-semiconductor field-effect transistor (MOSFET), or may be other devices such as a diode, an electron tube, an electromechanical component, etc., which are not limited herein. A material of the metal substrate 120 may be copper, molybdenum-copper, tungsten-copper, etc. The metal substrate 120 may be configured to conduct heat and electricity for the chip 130. A coefficient of thermal expansion (CTE) of the metal substrate 120 may range from 5 ppm/° C. to 20 ppm/° C. The range of thermal expansion coefficient of the metal substrate 120 may match an expansion coefficient of the chip 130, thereby maintaining structural stability between thermal expansions of the chip 130 and the metal substrate 120, reducing stress caused by differences in the thermal expansions, and improving the connection stability between the chip 130 and the metal substrate 120.

The chip embedded package 100 may include a plurality of chip units 112 and one of the chip units 112 may include a plurality of chips 130, which are set according to actual needs.

At least one mounting groove 111 may be formed on a first side 117 of the base circuit board 110. Each of the chip unit 112 may be fixedly mounted in a corresponding one of the at least one mounting groove 111. The mounting groove 111 may be a through groove. The base circuit board 110 may be arranged with one or more chip units 112. The first side 117 of the base circuit board 110, a first side of the metal substrate 120, and a first side of the chip 130 may be the same side.

The encapsulation layer 140 may be attached to the first side 117 of the base circuit board 110 and fill a gap between the base circuit board 110 and the at least one chip unit 112 for insulation encapsulation and device fixation. The encapsulation layer 140 may include, but may not be limited to, one or more of insulating materials such as epoxy resin, polyester resin (PET), polyimide, polyimide-based, polycarbonate (PC), bismaleimide triazine (BT)-based, ajinomoto build film (ABF), FR4 resin, ceramic-based, etc.

An end of each of the plurality of connecting members 150 may be connected to a corresponding electrode of the chip 130, and another end of each connecting member 150 may extend to a first side of the encapsulation layer 140 to be exposed, so as to lead out a signal of the chip 130 to the outside.

A step defining a first surface 131 and a second surface 132 may be formed on the first side of the metal substrate 120. The chip 130 may be fixedly connected to the second surface 132. The first surface 131 may protrude from the second surface 132, and the second surface 132 may extend to at least one edge of the metal substrate 120. That is, a thickness of the metal substrate 120 corresponding to the second surface 132 may be less than a thickness of the metal substrate 120 corresponding to the first surface 131.

The connecting members 150 may include a first connecting member 151. An end of the first connecting member 151 is connected to the first side of the chip 130. Another end of the first connecting member 151 may cross the second surface 132 in the encapsulation layer 140 to extend horizontally to the first side 117 of the base circuit board 110, and may extend to a board edge along the first side 117 of the base circuit board 110 to be exposed. A projection of the first connecting member 151 projected on the metal substrate 120 may be entirely located on the second surface 132. The board edge in the embodiments may refer to an edge region, and the connecting member is not only exposed from an edge. The edge region may have a certain width, and a portion of the connecting member may be disposed within the edge region with the certain width and wrapped by a board to improve the insulation effect.

The chip embedded package 100 may need to lead the signal of the chip 130 to the board edge for connection with an external device. The chip embedded package 100 may include a plurality of chips 130, and in a case where signals of the plurality of chips 130 are led to the board edge, horizontal routing may be usually required. However, a lead-out signal from the top of the chip 130 and a lead-out signal from the bottom of the chip 130 may belong to different connection networks. Therefore, in the embodiments, a step structure may be formed to ensure the electrical insulation of horizontal routing and reduce a height of the second surface 132. Thus, in a case where the first connecting member 151 corresponding to the chip 130 crosses the second surface 132 in the encapsulation layer 140 to horizontally extend to the first side 117 of the base circuit board 110, the step may be formed to increase a distance between the second surface 132 and the first connecting member 151, thereby ensuring the electrical insulation between the second surface 132 and the first connecting member 151, that is, ensuring the electrical insulation between different lead-out signals of the chip 130 and other connection networks during horizontal routing. A second side of the base circuit board 110 may insulate the metal substrate 120 from the outside by means of laminating an insulating layer or providing other insulating structures.

Moreover, after crossing the second surface 132, the first connecting member 151 of the embodiment may extend to the board edge along the first side 117 of the base circuit board 110. This not only allows the encapsulation layer 140 to wrap the portion of the first connecting member 151 to reduce electrical leakage or electrical breakdown between the first connecting member 151 and the outside, but also reserves more wiring space for other conductive circuits in a region of the encapsulation layer 140 corresponding to an extension region of the first connecting member 151, increasing the wiring flexibility of the chip embedded package 100.

Through the above structure, the chip embedded package of the embodiments may form the step defining the first surface and the second surface on the first side of the metal substrate to reduce the height of the second surface. Thus, in a case where the first connecting member corresponding to the chip crosses the second surface in the encapsulation layer to horizontally extend to the first side of the base circuit board, the step may be formed to increase the distance between the second surface and the first connecting member, thereby ensuring the electrical insulation between the second surface and the first connecting member, that is, ensuring the electrical insulation of different lead-out signals of the chip during horizontal routing. In this way, the safety and reliability of the chip embedded package are improved. Moreover, after crossing the second surface, the first connecting member may extend to the board edge along the first side of the base circuit board. This not only allows the encapsulation layer to wrap the portion of the first connecting member to reduce electrical leakage or electrical breakdown between the first connecting member and the outside, but also reserves more wiring space for other conductive circuits in a region of the encapsulation layer corresponding to an extension region of the first connecting member, increasing the wiring flexibility of the chip embedded package.

As shown in FIG. 2, FIG. 2 is a schematic structural view of a chip embedded package according to a second embodiment of the present disclosure.

Positions and connection relationships of a base circuit board 210, at least one chip unit, an encapsulation layer L, and a plurality of connecting members of a chip embedded package 200 of the embodiment may be the same as those of the previous embodiment. The embodiment may further include structures as follows.

In some embodiments, the encapsulation layer L may include a filling layer L0, a first layer L1, and a second layer L2. The filling layer L0 may be disposed in a mounting groove 211 and fill gaps between the mounting groove 211 and the chip unit. The second layer L2 may be stacked and attached to a first side of the base circuit board 210. The first layer L1 may be stacked and attached to a side of the second layer L2 away from the base circuit board 210. The filling layer L0, the first layer L1, and the second layer L2 may be integrated after lamination.

An end of a first connecting member 250 away from a chip 220 may cross a second surface 232 on the side of the second layer L2 away from the base circuit board 210 to horizontally extend to the first side of the base circuit board 210. In this way, a distance between a portion of the first connecting member 250 crossing the second surface 232 and the second surface 232 may include a thickness of the second layer L2 and a thickness of the filling layer L0, thereby increasing the distance between the first connecting member 250 and the second surface 232 and achieving insulation via the encapsulation layer L. Furthermore, electrical leakage or electrical breakdown between the first connecting member 250 and the second surface 232 may be reduced, thereby ensuring the electrical insulation between the second surface 232 and the first connecting member 250. Moreover, the portion of the first connecting member 250 crossing the second surface 232 may be disposed between the first layer L1 and the second layer L2, which may further reduce electrical leakage or electrical breakdown between the first connecting member 250 and the outside, and further improve the overall insulation effect, safety, and reliability of the chip embedded package 200.

In some embodiments, a first side of the chip 220 may be defined with a gate 221 and a transfer electrode 222. A second side of the chip 220 may be defined with another transfer electrode 223. The first connecting member 250 may be connected to the transfer electrode 222 on the first side of the chip 220 to lead a signal of the transfer electrode to the board edge for connection with the external device. A metal substrate 230 may be connected to another transfer electrode 223 on the second side of the chip 220.

The chip 220 may include a power chip such as an IGBT (insulated gate bipolar transistor) chip or a MOSFET (metal-oxide-semiconductor field-effect transistor) chip.

The transfer electrode 222/223 may include a current input stage and a current output stage. In a case where the chip 220 is an insulated gate bipolar transistor, the transfer electrode 222/223 may be an emitter or a collector. In a case where the chip 220 is a metal-oxide-semiconductor field-effect transistor, the transfer electrode 222/223 may be a source or a drain. Types of one transfer electrode 222 connected to the first connecting member 250 and another transfer electrode 223 connected to the metal substrate 230 may be arbitrarily set or exchanged based on a chip type and actual needs, which are not limited herein. For example, in a case where the chip 220 is a metal-oxide-semiconductor field-effect transistor, the electrode 222 connected to the first connecting member 250 may be a source and the electrode 223 connected to the metal substrate 230 may be a drain, or the electrode 222 connected to the first connecting member 250 may be a drain and the electrode 223 connected to the metal substrate 230 may be a source.

In some embodiments, the first connecting member 250 may include a crossing part 251, a first extending part 252, and a first vertical part 253, which are connected in sequence.

An end of the crossing part 251 may be connected to the first side of the chip 220. The end of the crossing part 251 may be connected to the transfer electrode 222 on the first side of the chip 220. Another end of the crossing part 251 may cross the second surface 232 on a side of the second layer L2 away from the base circuit board 210, so as to reach the first side of the base circuit board 210. The crossing part 251 may be configured to transmit a signal of the transfer electrode 222 on the first side of the chip 220 to the first side of the base circuit board 210.

An end of the first extending part 252 may be connected to the another end of the crossing part 251. Another end of the first extending part 252 may extend to the board edge along the first side of the base circuit board 210. The first extending part 252 may be configured to transmit the signal of the transfer electrode 222 on the first side of the chip 220 to the edge of the first side of the base circuit board 210.

The first vertical part 253 may be disposed at the board edge in the encapsulation layer L. An end of the first vertical part 253 may be connected to the another end of the first extending part 252. Another end of the first vertical part 253 may penetrate the second layer L2 and the first layer L1 in sequence to be exposed on a first side of the encapsulation layer L. The first vertical part 253 may be configured to vertically transmit the signal at the edge of the first side of the base circuit board 210 to an edge outside the first layer L1 for external connection.

With the above structure, the crossing part 251 combined with the second surface 232 with reduced height may increase a vertical distance between the first connecting member 250 and the another transmission network at the bottom of the chip 220, i.e., the second surface 232, may reduce electrical leakage or electrical breakdown between the first connecting member 250 and the second surface 232, and may ensure the electrical insulation between the second surface 232 and the first connecting member 250. The first extending part 252 may extend toward the board edge on the first side of the base circuit board 210 to reserve a space of the first layer L1 and the second layer L2 corresponding to the first extending part 252, so as to facilitate the wiring of a conductive circuit 290. The first connecting member 250 may vertically lead the signal at the edge of the first side of the base circuit board 210 to the edge of the side of the first layer L1 away from the base circuit board 210, thereby facilitating external connection.

In some embodiments, thicknesses of the circuits and the connecting members on the first side of the base circuit board 210 may be greater than or equal to 100 microns, so as to meet conduction requirements of various connecting members and circuits.

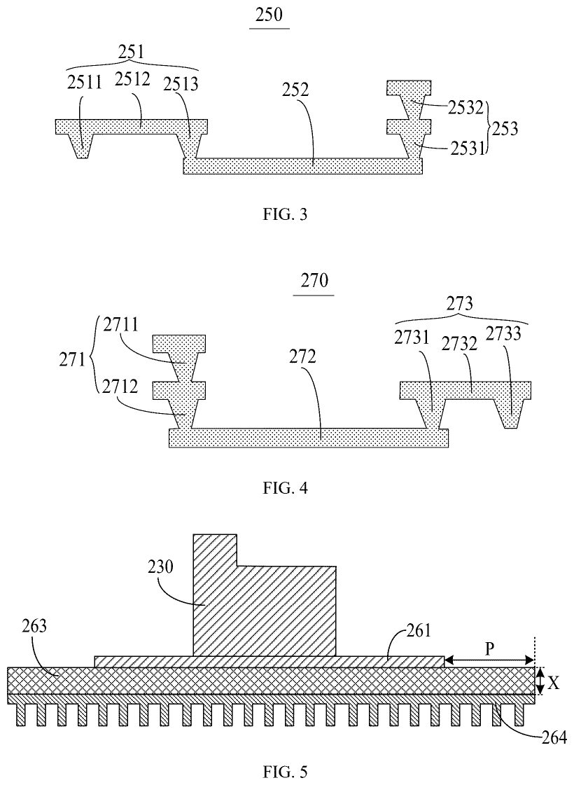

As shown in FIG. 3, FIG. 3 is an enlarged schematic view of a first connecting member shown in FIG. 2.

In some embodiments, the crossing part 251 may include a first connecting hole 2511, a crossing portion 2512, and a second connecting hole 2513, which are connected in sequence. Each connecting hole in the embodiments may be a metallized hole with electrically conductive capability.

The first connecting hole 2511 and the second connecting hole 2513 may be disposed in the second layer L2. The crossing portion 2512 may be attached to the side of the second layer L2 away from the base circuit board 210. An end of the first connecting hole 2511 may be connected to the first side of the chip 220. Another end of the first connecting hole 2511 may be connected to an end of the crossing portion 2512. Another end of the crossing portion 2512 may be connected to an end of the second connecting hole 2513. Another end of the second connecting hole 2513 may be connected to the end of the first extending part 252 on the first side of the base circuit board 210.

That is, the first connecting hole 2511, the crossing portion 2512, and the second connecting hole 2513 may form a bridge structure. The crossing part 251 may be first led up to the second layer L2 via the first connecting hole 2511, and then led down to the first side of the base circuit board 210 after crossing the second surface 232, thereby increasing the distance between the first connecting member 250 and the second surface 232 along an upward direction. The second surface 232 may increase the distance between the first connecting member 250 and the second surface 232 along a downward direction, thereby doubly increasing the distance between the first connecting member 250 and the second surface 232.

The first vertical part 253 may include a third connecting hole 2531 and a fourth connecting hole 2532 connected in sequence. The third connecting hole 2531 may be disposed in the second layer L2. The fourth connecting hole 2532 may be disposed in the first layer L1. An end of the third connecting hole 2531 may be connected to the another end of the first extending part 252. An end of the fourth connecting hole 2532 away from the third connecting hole 2531 may be exposed on the first side of the encapsulation layer L. The third connecting hole 2531 and the fourth connecting hole 2532 may form vertical stacked holes to lead up the signal. To prevent external leakage of the first connecting member 250, it is necessary to set the encapsulation layer L with a sufficient thickness on the first side of the base circuit board 210. However, if the first layer L1 and the second layer L2 are laminated at a single time, the first vertical part 253 may not be filled by electroplating due to an excessive thickness of the single lamination. Therefore, through a dual arrangement of the first layer L1 and the second layer L2 and a dual stacked hole design corresponding to the first vertical part 253, both the thickness of the encapsulation layer L on the first side of the base circuit board 210 and the conduction capability of the first vertical part 253 may be ensured.

As shown in FIG. 2, the connecting members may further include a second connecting member 270. The second connecting member 270 may include a conducting part 273, a second extending part 272, and a second vertical part 271, which are connected in sequence.

An end of the conducting part 273 may be connected to the first surface 231. Since the chip 220 is connected to the second surface 232, the conducting part 273 may be actually connected to the another transfer electrode 223 on the second side of the chip 220 via the metal substrate 230. A signal of the another transfer electrode 223 may be led up via the first surface 231 of the metal substrate 230.

Another end of the conducting part 273 may reach the first side of the base circuit board 210. The conducting part 273 may be configured to transmit the signal of the transfer electrode 223 on the second side of the chip 220 from the first surface 231 to the first side of the base circuit board 210. The first side of the base circuit board 210 contacted with the conducting part 273 of the second connecting member 270 and the first side of the base circuit board 210 contacted with the first connecting member 250 may be different regions at different positions for mutual insulation.

An end of the second extending part 272 may be connected to the another end of the conducting part 273. Another end of the second extending part 272 may extend to the board edge along the first side of the base circuit board 210. The second extending part 272 may be configured to transmit the signal of the transfer electrode 223 on the second side of the chip 220 to another edge of the first side of the base circuit board 210, i.e., an edge different from the edge corresponding to the first connecting member 250.

The second vertical part 271 may be disposed at the board edge in the encapsulation layer L. An end of the second vertical part 271 may be connected to the another end of the second extending part 272. Another end of the second vertical part 271 may penetrate the second layer L2 and the first layer L1 in sequence to be exposed on the first side of the encapsulation layer L. The second vertical part 271 may be configured to vertically transmit the signal corresponding to the another edge of the first side of the base circuit board 210 to another edge outside the first layer L1 for external connection, i.e., an edge different from the edge corresponding to the first connecting member 250.

With the above structure, the conducting part 273 may connect the first surface 231 and the first side of the base circuit board 210 to transmit a signal. The second extending part 272 may extend toward the edge on the first side of the base circuit board 210 to reserve a space of the first layer L1 and the second layer L2 corresponding to the second extending part 272, so as to facilitate the wiring of a conductive circuit. The second connecting member 270 may vertically lead the signal at the another edge of the first side of the base circuit board 210 to the another edge of the side of the first layer L1 away from the base circuit board 210, thereby facilitating external connection.

As shown in FIG. 4, FIG. 4 is an enlarged schematic view of a second connecting member shown in FIG. 2.

The conducting part 273 may include a fifth connecting hole 2733, a conducting portion 2732, and a sixth connecting hole 2731, which are connected in sequence. Each connecting hole in the embodiments may be a metallized hole with electrically conductive capability.

The fifth connecting hole 2733 and the sixth connecting hole 2731 may be disposed in the second layer L2. The conducting portion 2732 may be attached to the side of the second layer L2 away from the base circuit board 210. An end of the fifth connecting hole 2733 may be connected to the first surface 231. Another end of the fifth connecting hole 2733 may be connected to an end of the conducting portion 2732. Another end of the conducting portion 2732 may be connected to an end of the sixth connecting hole 2731. Another end of the sixth connecting hole 2731 may be connected to an end of the second extending part 272.

The fifth connecting hole 2733, the conducting portion 2732, and the sixth connecting hole 2731 in the embodiment may form a bridge structure. The conducting part 273 may be first led up to the second layer L2 via the fifth connecting hole 2733, and then led down to the first side of the base circuit board 210 after crossing the mounting groove 211. In other embodiments, the conducting part 273 may further include other structures, such as a connecting part directly horizontally connecting the first surface 231 and the first side of the base circuit board 210, etc. The connecting structure of the conducting part 273 may not be limited and may be determined based on process selection. The first surface 231 may be flush with the first side of the base circuit board 210.

The second vertical part 271 may include a seventh connecting hole 2712 and an eighth connecting hole 2711 connected in sequence. The seventh connecting hole 2712 may be disposed in the second layer L2. The eighth connecting hole 2711 may be disposed in the first layer L1. An end of the seventh connecting hole 2712 may be connected to the another end of the second extending part 272. An end of the eighth connecting hole 2711 away from the seventh connecting hole 2712 may be exposed on the first side of the encapsulation layer L. To prevent external leakage of the second connecting member 270, it is necessary to set the encapsulation layer L with a sufficient thickness on the first side of the base circuit board 210. However, if the first layer L1 and the second layer L2 are laminated at a single time, the second vertical part 271 may not be filled by electroplating due to an excessive thickness of the single lamination. Therefore, through the dual arrangement of the first layer L1 and the second layer L2 and a dual stacked hole design corresponding to the second vertical part 271, both the thickness of the encapsulation layer L on the first side of the base circuit board 210 and the conduction capability of the second vertical part 271 may be ensured.

As shown in FIG. 2, in some embodiments, the chip embedded package 200 may further include a third connecting member 280. An end of the third connecting member 280 may be connected to the gate 221 on the first side of the chip 220. Another end of the third connecting member 280 may pass through the encapsulation layer L and may be exposed on the first side of the encapsulation layer L.

In an application scenario, the third connecting member 280 may include a ninth connecting hole 281 and a tenth connecting hole 282 connected in a stacked manner. An end of the ninth connecting hole 281 may be connected to the gate 221 on the first side of the chip 220. An end of the tenth connecting hole 282 away from the ninth connecting hole 281 may be exposed on the first layer L1.

In another application scenario, the third connecting member 280 may include a metal base. The metal base may be inserted into the first layer L1 and the second layer L2 to be connected to the gate 221 of the chip 220. The structure of the third connecting member 280 may not be limited herein.

After being exposed on the first layer L1, the third connecting member 280 may further extend to an edge of the first layer L1 to facilitate connection with external structures.

In some embodiments, the chip embedded package 200 may further include the conductive circuit 290. The conductive circuit 290 may be a basic circuit for realizing electrical functions on the chip embedded package 200.

The conductive circuit 290 may be disposed on the first side of the base circuit board 210 and/or the side of the first layer L1 away from the base circuit board 210. Distances between the conductive circuit 290 and the connecting members may be respectively greater than 0.3 millimeters to standardize a minimum distance between different connection networks in the chip embedded package 200 and ensure the electrical insulation between the connection networks.

A distance between different connection networks may include, but not be limited to, 0.3 millimeters, 0.4 millimeters, 0.5 millimeters, 0.8 millimeters, 1.0 millimeters, 2.0 millimeters, or 3.0 millimeters, etc.

A thickness of the base circuit board 210, a distance between each connecting member and the metal substrate 230, and a distance between a horizontal routing region of the connecting member connected to the transfer electrode 222/223 of the chip 220 and the outside may all be greater than 0.3 millimeters, so as to further improve the overall electrical insulation effect of the chip embedded package 200.

In some embodiments, the chip embedded package 200 may further include a heat dissipation device 267. The heat dissipation device 267 may be attached to a second side of the base circuit board 210. The second side of the base circuit board 210 may be an opposite side of the first side of the base circuit board 210. A second side of the metal substrate 230, the second side of the base circuit board 210, and the second side of the chip 220 may be the same side.

The heat dissipation device 267 may include an insulating plate 260 and a heat sink 264. The insulating plate 260 may be fixedly attached to the second side of the base circuit board 210. The heat sink 264 may be fixedly attached to a side of the insulating plate 260 away from the base circuit board 210.

The heat dissipation device 267 of the embodiment may be obtained by welding the insulating plate 260 on the heat sink 264. The welding may include solder reflow soldering, silver sintering, etc. The heat sink 264 may include a metal heat sink, an air-cooled heat sink, or a liquid-cooled heat sink.

In an application scenario, the heat sink 264 may include a protruding heat dissipation structure 266 and a main plate 265. The main plate 265 may be fixedly attached to the side of the insulating plate 260 away from the second side of the base circuit board 210. The protruding heat dissipation structure 266 may be fixedly disposed on a side of the main plate 265 away from the insulating plate 260. A shape of the protruding heat dissipation structure 266 may include, but not be limited to, one or more of columnar, corrugated, finned, etc. A material of the heat sink 264 may include, but not be limited to, copper, aluminum, stainless steel, etc.

By fixing and attaching the insulating plate 260 to the second side of the base circuit board 210, the insulating plate 260 may be used to achieve insulation protection for the second side of the base circuit board 210, preventing electrical leakage from the second side of the base circuit board 210 to the heat sink 264 or the outside.

In some embodiments, the insulating plate 260 may include a first metal layer 261, an insulating layer 263, and a second metal layer 262, which are stacked and attached in sequence. The first metal layer 261 may further be attached to the second side of the metal substrate 230. The second metal layer 262 may further be attached to a side of the heat sink 264 close to the metal substrate 230.

The first metal layer 261 may be configured to realize the welding and fixing between the metal substrate 230 and the insulating layer 263. The second metal layer 262 may be configured to realize the welding and fixing between the insulating layer 263 and the heat sink 264. A position of the insulating layer 263 and the heat sink 264 is fixed via the stacked insulating plate 260.

A way of attaching and fixing the first metal layer 261 and the second metal layer 262 may adopt direct bonding or welding.

Thicknesses of the first metal layer 261 and the second metal layer 262 may respectively range from 0.01 mm to 1.00 mm, such as 0.05 mm, 0.11 mm, 0.17 mm, 0.25 mm, 0.3 mm, 0.45 mm, 0.52 mm, 0.63 mm, 0.75 mm, 0.8 mm, 0.95 mm, or 1.00 mm, etc. The thickness of the first metal layer 261 may be the same as or different from the thickness of the second metal layer 262. Materials of the first metal layer 261 and the second metal layer 262 may respectively include one or more of copper, aluminum, silver, titanium, tin, molybdenum, and tungsten.

The insulating plate 260 of the embodiment may be pre-produced and then welded and fixed to the base circuit board 210, so as to realize high-temperature welding of the first metal layer 261 and the second metal layer 262 with the insulating layer 263 independently, and reduce the impact of high temperature on the reliability of the base circuit board 210.

In some embodiments, the first metal layer 261 may be attached to the second side of the base circuit board 210 and the second side of the metal substrate 230.

A length of a side connection path between a side surface of the first metal layer 261 and the heat sink 264 may be greater than 0.3 millimeters. Since the first metal layer 261 is connected to the metal substrate 230, the first metal layer 261 may belong to the connection networks. Therefore, the length of the side connection path between the side surface of the first metal layer 261 and the heat sink 264 may be limited to be greater than 0.3 millimeters, that is, a sum of a distance from a side edge of the first metal layer 261 to a side edge of the insulating layer 263 and a thickness of the insulating layer 263 may be at least greater than 0.3 millimeters, which may be realized by retracting the first metal layer 261. A retracted region of the first metal layer 261 may be filled with an encapsulation material on the base circuit board 210.

As shown in FIG. 5, FIG. 5 is a partial structural schematic view between a metal substrate and a heat sink according to some embodiments of the present disclosure.

A side connection path S between the metal substrate 230 and the heat sink 264 may include a distance P between an edge of a connection network where the metal substrate 230 is located and an edge of the insulating plate 260 and a thickness X of the insulating layer 263. That is, S=P+X. In this way, a minimum length of a path that current may break down may need to be greater than 0.3 millimeters, so as to prevent electrical breakdown and improve the external insulation effect of the metal substrate 230.

The distance P of the embodiment may be a distance between the edge of the first metal layer 261 and the edge of the insulating plate 260.

The structure of the above chip embedded package 200 may adopt the first metal layer 261 to realize the fixation between the metal substrate 230 and the insulating layer 263, adopt the second metal layer 262 to realize the fixation between the insulating layer 263 and the heat sink 264, and adopt the metal substrate 230 to improve the heat dissipation efficiency of the chip embedded package 200.

In some embodiments, the insulating layer 263 of the insulating plate 260 may include a ceramic layer and/or a resin layer.

In a case where the insulating layer 263 is a ceramic layer, a thickness of the ceramic layer may be greater than 0.05 millimeters, such as 0.05 mm, 0.10 mm, 0.16 mm, 0.25 mm, 0.32 mm, 0.45 mm, 0.52 mm, 0.68 mm, 0.71 mm, 0.8 mm, 0.95 mm, or 1.00 mm, etc. The insulating layer 263 with a thickness within this range may realize the insulation protection for the bottom of the base circuit board 210.

The insulating layer 263 may be one or more of aluminum oxide, silicon nitride, aluminum nitride, beryllium oxide, diamond, etc. The above ceramic materials may ensure the thermal conductivity of the insulating layer 263 on the premise of realizing insulation protection, making the thermal conductivity of the insulating layer 263 reach 80 W/mK or even 1200 W/mK, which may be far higher than the thermal conductivity of materials such as thermal grease and resin, and realizing a significant improvement in heat dissipation efficiency.

In some embodiments, in a case where the insulating layer 263 is a ceramic layer, the first metal layer 261 may be welded and attached to the second side of the metal substrate 230 via a welding layer (not shown in the drawings). The welding layer may include a solder layer close to the first metal layer 261 and a welding auxiliary metal layer covering surfaces of the second side of the metal substrate 230 and the second side of the base circuit board 210. A size of the ceramic layer may be larger than a size of the metal substrate 230 but not larger than a size of the base circuit board 210.

In a case where the insulating layer 263 is a resin layer, a thickness of the resin layer may be greater than 0.3 millimeters, which may include, but not be limited to, 0.3 millimeters, 0.5 millimeters, 0.6 millimeters, 0.8 millimeters, 1.0 millimeters, or 1.5 millimeters, etc.

The resin layer may include, but not be limited to, one or more of insulating materials such as prepreg, epoxy resin, polyester resin (PET), polyimide, polyimide-based, polycarbonate (PC), bismaleimide triazine (BT)-based, Ajinomoto build film (ABF), FR4 resin, ceramic-based, etc.

In some embodiments, in a case where the insulating layer 263 is a resin layer, the first metal layer 261 may be omitted, and the insulating layer 263 may be directly attached to the second side of the metal substrate 230 by means of resin bonding.

In some embodiments, a step height difference between the first surface 231 and the second surface 232 may be close to a thickness of the chip 220. The step height difference may range from −10% to +20% relative to the thickness of the chip 220, so as to facilitate the connection between the first surface 231 and the first side of the chip 220 with corresponding connecting members.

In some embodiments, the second surface 232 may need to extend to at least one side edge of the metal substrate 230 to facilitate the disposing of the crossing part 251 using the extension of the second surface 232, so that a projection of the crossing part 251 projected on the metal substrate 230 may be entirely located on the second surface 232, that is, an entire region under the crossing part 251 may be the second surface 232. In this way, it not only ensures the insulation between the crossing part 251 and the second surface 232, but also enables the crossing part 251 to be led to the first side of the base circuit board 210 after extending horizontally over a shortest possible distance.

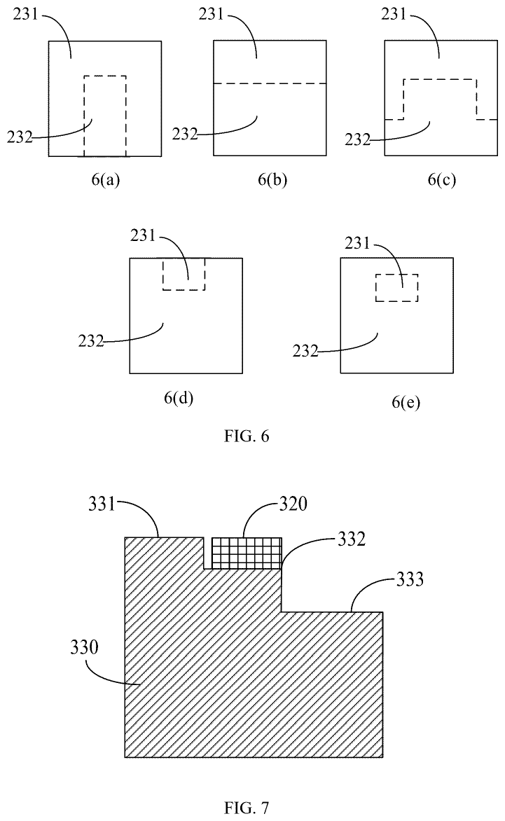

As shown in FIG. 6, FIG. 6 is a top schematic view of a first side of a metal substrate according to some embodiments of the present disclosure.

As shown in 6(a) of FIG. 6, which is an embodiment where the second surface 232 may extend to one side of the metal substrate 230.

As shown in 6(b) of FIG. 6, which is an embodiment where the second surface 232 may extend to three sides of the metal substrate 230.

As shown in 6(c) of FIG. 6, which is another embodiment where the second surface 232 may extend to three sides of the metal substrate 230.

As shown in 6(d) of FIG. 6, which is further another embodiment where the second surface 232 may extend to three sides of the metal substrate 230.

As shown in 6(e) of FIG. 6, which is an embodiment where the second surface 232 may extend to four sides of the metal substrate 230.

The arrangement of the second surface 232 and the first surface 231 may not be limited herein and may be set based on actual needs.

As shown in FIG. 7, FIG. 7 is a schematic structural view of a metal substrate according to another embodiment of the present disclosure.

In some embodiments, a side of a chip 320 away from a metal substrate 330 may be flush with a first surface 331.

In a case where a thickness of the chip 320 is relatively small and a first side of the chip 320 needs to be flush with the first surface 331, a height of a second surface 332 may be reduced insufficiently to meet the insulation requirements. Therefore, in the embodiments, the step may further include a third surface 333. The second surface 332 may protrude from the third surface 333. The second surface 332 may be configured to mount the chip. The third surface 333 may be configured to increase an insulation distance.

The another end of the first connecting member may cross the third surface 333 in the encapsulation layer to horizontally extend to the first side of the base circuit board. That is, the projection of the first connecting member on the metal substrate 330 may be entirely located on the third surface 333.

A combined shape of the second surface 332 and the third surface 333 may be similar to a combined shape of the first surface and the second surface in the aforementioned FIG. 6, which will not be repeated.

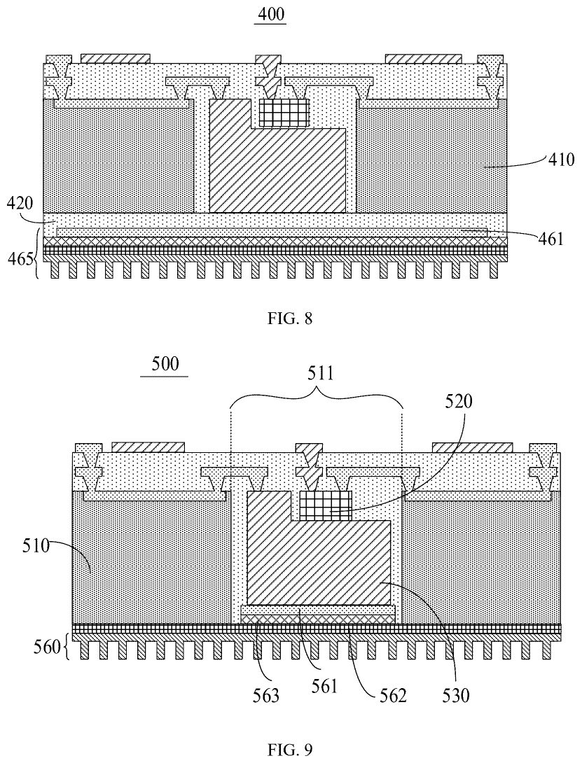

As shown in FIG. 8, FIG. 8 is a schematic structural view of a chip embedded package according to a third embodiment of the present disclosure.

In a chip embedded package 400 of the embodiment, a laminated insulating layer 420 may be further disposed between a base circuit board 410 and a heat dissipation device 465 to form a symmetric lamination with the first layer and the second layer, alleviate the internal stress of a single upper layer, and reduce product warpage. A thickness of the laminated insulating layer 420 may be the same as or close to a sum of thicknesses of the first layer and the second layer. A side of the laminated insulating layer 420 may be attached to a second side of the base circuit board 410. Another side of the laminated insulating layer 420 may be attached to a first metal layer 461.

Other structures such as an electrical circuit or a heat dissipation member may be disposed in the laminated insulating layer 420, which may be set based on actual needs. Other conductive circuits may be disposed on a second side of the base circuit board 410.

Other features of the chip embedded package 400 of the embodiment may be the same as those of the previous embodiment, please refer to the previous description, which will not be repeated.

As shown in FIG. 9, FIG. 9 is a schematic structural view of a chip embedded package according to a fourth embodiment of the present disclosure.

In some embodiments, a projection size of an insulating layer 563 projected on a base circuit board 510 may be smaller than a projection size of a mounting groove 511 projected on the base circuit board 510, and the projection size of the insulating layer 563 projected on the base circuit board 510 may be larger than a projection size of a metal substrate 530 projected on the base circuit board 510. That is, an overlapping portion between the metal substrate 530 and a heat sink 560 must be isolated and insulated by the insulating layer 563 to improve the insulation effect of the metal substrate 530.

A projection size of the first metal layer projected on the base circuit board 510 may not be smaller than the projection size of the metal substrate 530 projected on the base circuit board 510.

A side of the insulating layer 563 away from the chip 520 may be flush with a second side of the base circuit board 510.

The structure of the above chip embedded package 500 may directly arrange the insulating layer 563 in the mounting groove 511 to provide another insulating structure for the second side of the metal substrate 530. The above arrangement may also adopt the first metal layer 561 to realize the fixation between the metal substrate 530 and the insulating layer 563, adopt a second metal layer 562 to realize the fixation between the insulating layer 563 and the heat sink 560, and adopt the metal substrate 530 to improve the heat dissipation efficiency of the chip embedded package 500.

Other features of the chip embedded package 500 of the embodiment may be the same as those of the previous embodiment, please refer to the previous description, which will not be repeated.

Through the above structure, the chip embedded package of the embodiments may form the step defining the first surface and the second surface on the first side of the metal substrate to reduce the height of the second surface. Thus, in a case where the first connecting member corresponding to the chip may cross the second surface in the encapsulation layer to horizontally extend to the first side of the base circuit board, the step may be disposed to increase the distance between the second surface and the first connecting member, thereby ensuring the electrical insulation between the second surface and the first connecting member, that is, ensuring the electrical insulation of different lead-out signals of the chip during horizontal routing. In this way, the safety and reliability of the chip embedded package may be improved. Moreover, after crossing the second surface, the first connecting member may extend to the board edge along the first side of the base circuit board. This not only allows the encapsulation layer to wrap the portion of the first connecting member to reduce electrical leakage or electrical breakdown between the first connecting member and the outside, but also reserves more wiring space for other conductive circuits in a region of the encapsulation layer corresponding to an extension region of the first connecting member, increasing the wiring flexibility of the chip embedded package. The embodiments of the present disclosure may standardize a shape of the metal substrate in the component and a layout method of various circuits, ensure the electrical insulation of high-voltage circuits, and reduce the risk of electrical aging and insulation failure of the component under operating conditions of high-voltage and high-switching-frequency.

The above are only the embodiments of the present disclosure, and are not intended to limit the patent scope of the present disclosure. Any equivalent structure or equivalent process transformation made based on the content of the description and drawings of the present disclosure, or directly or indirectly applied in other related technical fields, is similarly included in the patent protection scope of the present disclosure.

1. A chip embedded package, comprising:
a base circuit board, wherein at least one mounting groove is defined on a first side of the base circuit board;
at least one chip unit, wherein each of the at least one chip unit is fixedly mounted in a corresponding one of the at least one mounting groove, and each of the at least one chip unit comprises at least one metal substrate and at least one chip; a step defining a first surface and a second surface is formed on a first side of each of the at least one metal substrate, and a corresponding one of the at least one chip is fixedly connected to the second surface; wherein the first surface protrudes from the second surface, and the second surface extends to at least one side edge of a corresponding one of the at least one metal substrate;
an encapsulation layer, attached to the first side of the base circuit board and filling gaps between the base circuit board and the at least one chip unit;
a plurality of connecting members, wherein an end of each of the plurality of connecting members is connected to a corresponding electrode of a corresponding one of the at least one chip, and another end of each of the plurality of connecting members extends to a first side of the encapsulation layer to be exposed;
wherein the plurality of connecting members comprise a first connecting member, an end of the first connecting member is connected to a first side of a corresponding one of the at least one chip, and another end of the first connecting member crosses the second surface in the encapsulation layer to horizontally extend to the first side of the base circuit board, and extends to an board edge along the first side of the base circuit board to be exposed; wherein a projection of the first connecting member projected on a corresponding one of the at least one metal substrate is entirely located on the second surface.

2. The chip embedded package according to claim 1, wherein the encapsulation layer comprises a filling layer, a first layer, and a second layer, the filling layer is disposed in the at least one mounting groove, the second layer is stacked and attached to the first side of the base circuit board, and the first layer is stacked and attached to a side of the second layer away from the base circuit board;
the another end of the first connecting member crosses the second surface on the side of the second layer away from the base circuit board to horizontally extend to the first side of the base circuit board.

3. The chip embedded package according to claim 2, wherein
the first side of the corresponding one of the at least one chip is disposed with a gate and a transfer electrode, and a second side of the corresponding one of the at least one chip is disposed with another transfer electrode; the first connecting member is connected to the transfer electrode on the first side of the corresponding one of the at least one chip to lead a signal of the transfer electrode to the board edge for connection with an external device, and the corresponding one of the at least one metal substrate is connected to the another transfer electrode on the second side of the corresponding one of the at least one chip.

4. The chip embedded package according to claim 2, wherein
the first connecting member comprises a crossing part, a first extending part, and a first vertical part, which are connected in sequence;
an end of the crossing part is connected to the first side of the corresponding one of the at least one chip, and another end of the crossing part crosses the second surface on the side of the second layer away from the base circuit board to reach the first side of the base circuit board;
an end of the first extending part is connected to the another end of the crossing part, and another end of the first extending part extends to the board edge along the first side of the base circuit board;
the first vertical part is disposed in the encapsulation layer and located at the board edge; an end of the first vertical part is connected to the another end of the first extending part, and another end of the first vertical part penetrates the second layer and the first layer in sequence to be exposed on the first side of the encapsulation layer.

5. The chip embedded package according to claim 4, wherein
the crossing part comprises a first connecting hole, a crossing portion, and a second connecting hole, which are connected in sequence; the first connecting hole and the second connecting hole are disposed in the second layer, and the crossing portion is attached to the side of the second layer away from the base circuit board; an end of the first connecting hole is connected to the first side of the corresponding one of the at least one chip, another end of the first connecting hole is connected to an end of the crossing portion, the another end of the crossing portion is connected to an end of the second connecting hole, and another end of the second connecting hole is connected to the end of the first extending part.

6. The chip embedded package according to claim 4, wherein
the first vertical part comprises a third connecting hole and a fourth connecting hole connected in sequence, the third connecting hole is disposed in the second layer, the fourth connecting hole is disposed in the first layer, an end of the third connecting hole is connected to the another end of the first extending part, and an end of the fourth connecting hole away from the third connecting hole is exposed on the first side of the encapsulation layer.

7. The chip embedded package according to claim 3, wherein
the plurality of connecting members further comprise a second connecting member, and the second connecting member comprises a conducting part, a second extending part, and a second vertical part, which are connected in sequence;
an end of the conducting part is connected to the first surface, and another end of the conducting part reaches the first side of the base circuit board;
an end of the second extending part is connected to the another end of the conducting part, and another end of the second extending part extends to the board edge along the first side of the base circuit board;
the second vertical part is disposed at the board edge in the encapsulation layer, an end of the second vertical part is connected to the another end of the second extending part, and another end of the second vertical part penetrates the second layer and the first layer in sequence to be exposed on the first side of the encapsulation layer.

8. The chip embedded package according to claim 7, wherein
the conducting part comprises a fifth connecting hole, a conducting portion, and a sixth connecting hole, which are connected in sequence; the fifth connecting hole and the sixth connecting hole are disposed in the second layer, and the conducting portion is attached to the side of the second layer away from the base circuit board; an end of the fifth connecting hole is connected to the first surface, another end of the fifth connecting hole is connected to an end of the conducting portion, the another end of the conducting portion is connected to an end of the sixth connecting hole, and another end of the sixth connecting hole is connected to the end of the second extending part.

9. The chip embedded package according to claim 7, wherein
the second vertical part comprises a seventh connecting hole and an eighth connecting hole connected in sequence, the seventh connecting hole is disposed in the second layer, the eighth connecting hole is disposed in the first layer, an end of the seventh connecting hole is connected to the another end of the second extending part, and an end of the eighth connecting hole away from the seventh connecting hole is exposed on the first side of the encapsulation layer.

10. The chip embedded package according to claim 3, wherein the chip embedded package further comprises a third connecting member, an end of the third connecting member is connected to the gate on the first side of the corresponding one of the at least one chip, and another end of the third connecting member passes through the encapsulation layer and is exposed on the first side of the encapsulation layer.

11. The chip embedded package according to claim 10, wherein the third connecting member comprises a ninth connecting hole and a tenth connecting hole connected in a stacked manner, an end of the ninth connecting hole is connected to the gate on the first side of the corresponding one of the at least one chip, and an end of the tenth connecting hole away from the ninth connecting hole is exposed on the first layer.

12. The chip embedded package according to claim 10, wherein the third connecting member comprises a metal base, and the metal base is inserted into the first layer and the second layer to be connected to the gate of the corresponding one of the at least one chip.

13. The chip embedded package according to claim 2, wherein the chip embedded package further comprises a conductive circuit;
the conductive circuit is disposed on at least one of the first side of the base circuit board and a side of the first layer away from the base circuit board;
wherein a distance between the conductive circuit and each of the plurality of connecting members is greater than 0.3 millimeters.

14. The chip embedded package according to claim 1, wherein the chip embedded package further comprises a heat dissipation device;
the heat dissipation device is attached to a second side of the base circuit board, and the second side of the base circuit board is opposite to the first side of the base circuit board.

15. The chip embedded package according to claim 14, wherein
the heat dissipation device comprises an insulating plate and a heat sink; the insulating plate is fixedly attached to the second side of the base circuit board, and the heat sink is fixedly attached to a side of the insulating plate away from the base circuit board.

16. The chip embedded package according to claim 15, wherein
the heat sink comprises a protruding heat dissipation structure and a main plate, the main plate is fixedly attached to the side of the insulating plate away from the second side of the base circuit board, and the protruding heat dissipation structure is fixedly disposed on a side of the main plate away from the insulating plate.

17. The chip embedded package according to claim 16, wherein
a shape of the protruding heat dissipation structure comprises one or more of columnar, corrugated, and finned.

18. The chip embedded package according to claim 15, wherein
the insulating plate comprises a first metal layer, an insulating layer, and a second metal layer, which are stacked and attached in sequence, the first metal layer is further attached to a second side of the at least one metal substrate, and the second metal layer is further attached to a side of the heat sink close to the corresponding one of the at least one metal substrate;
the first metal layer is attached to the second side of the base circuit board and the second side of the at least one metal substrate;
wherein a length of a side connection path between a side surface of the first metal layer and the heat sink is greater than 0.3 millimeters.

19. The chip embedded package according to claim 1, wherein a side of each of the at least one chip away from a corresponding one of the at least one metal substrate is flush with the first surface;
the step is further defined with a third surface, and the second surface protrudes from the third surface;
the another end of the first connecting member crosses the third surface in the encapsulation layer to horizontally extend to the first side of the base circuit board.

20. The chip embedded package according to claim 1, wherein thicknesses of a circuit and the plurality of connecting members on the first side of the base circuit board are greater than or equal to 100 microns.
